(19) United States
(12) Patent Application Publication
(10) Pub. No.: US 2017/0256667 A1
(43) Pub. Date: Sep. 7, 2017

(54) GRAPHENE-SEMICONDUCTOR SCHOTTKY JUNCTION PHOTODETECTOR OF HAVING TUNABLE GAIN

(71) Applicant: GWANGJU INSTITUTE OF SCIENCE AND TECHNOLOGY, Gwangju (KR)

(72) Inventors: Byoung Hoon LEE, Gwangju (KR); Kyoung Eun CHANG, Gwangju (KR); Tae Jin YOO, Gwangju (KR); Hyeon Jun HWANG, Gwangju (KR)

(21) Appl. No.: 15/440,922

(22) Filed: Feb. 23, 2017

(30) Foreign Application Priority Data
Mar. 2, 2016 (KR) 10-2016-0024910

(51) Int. Cl. H01L 31/113; H01L 31/028

(52) U.S. Cl. CPC H01L 31/1136; H01L 31/028

(57) ABSTRACT

Disclosed herein is a photodetector utilizing graphene. A single-layer graphene channel is formed on a semiconductor substrate doped with n-type impurity. The graphene channel has an end connected to a source electrode and is physically separated from a drain electrode. Light having passed through a gate insulation layer and a gate electrode generates electron-hole pairs at the interface between the graphene channel and the semiconductor substrate forming a Schottky junction, and a photocurrent is generated by a Schottky barrier. In addition, the Schottky barrier is changed according to an applied gate voltage, thereby changing the photocurrent.

### CROSS-REFERENCE TO RELATED APPLICATIONS

This application claims the priority of Korean Patent Application No. 10-2016- 0024910 filed on Mar. 2, 2016, in the Korean intellectual Property Office, the disclosure of which is hereby incorporated by reference in its entirety.

### BACKGROUND

1. Technical Field

The present disclosure relates to a photodetector using graphene, and more particularly, to a photodetector that is capable of adjusting gain by applying a gate voltage and utilizes a Schottky junction between graphene and semiconductor.

2. Description of the Related Art

Graphene is a sheet-like material composed of sp² carbon-carbon bonds, and has zero band gap. That is, the bandgap of the graphene is close to zero, and the conduction band and the valence band have a conical shape within an extremely low range with respect to the Fermi level.

By utilizing such characteristics, there have been proposed transistors or photodetectors using graphene as a channel.

In particular, a photodetector has a structure that when a light is incident on an active region, it induces a change in current to form a photocurrent. For example, “Tunable graphene-silicon heterojunctions for ultrasensitive photodetection” by An, Xiaohong et al., (Nano letters, 2013) discloses an photodetector using Schottky junction between graphene and silicon. This is shown in FIG. 1.

FIG. 1 is a cross-sectional view showing a photodetector according to the prior art.

Referring to FIG. 1, a graphene layer 20 is formed on an n-type doped silicon substrate 10, and a silicon oxide 30 is formed on the right and left sides of the substrate 10. A source electrode 40 and a drain electrode 50 are formed on the silicon oxide 30. A gate electrode 60 is formed on the back surface of the silicon substrate 10. The graphene layer 20 is extended to the source electrode 40 and the drain electrode 50.

In the above structure, a Schottky junction is formed between the graphene layer 20 and the silicon substrate 10, thereby forming a diode structure. When light is incident, a photocurrent is generated, and such generation of the photocurrent takes place throughout the entire interface between the graphene layer 20 and the silicon substrate 10, and thus photoreactivity is significantly improved. However, there is a limitation in controlling the Fermi level of the graphene layer 20 since the silicon substrate 10 itself acts as a part of the gate electrode 60 or due to the action of the gate electrode 60 on the backside. In addition, the height of the Schottky barrier cannot be precisely controlled, such that there is a disadvantage that it exhibits low photoreactivity.

Korean Laid-Open Patent Publication No. 2013-0022852 discloses a graphene field effect transistor. Specifically, the field effect transistor disclosed therein includes a graphene layer and an adjustable barrier layer between a semiconductor layer and a first electrode. That is, the height of the barrier of the semiconductor layer is controlled by adjusting the voltage applied to the first electrode, thereby improving the on/off ratio. However, the gate electrode of the above disclosure is made of Au, which is an opaque metal, and is silent on use as a photodetector.

If the gain is adjusted according to the electric field applied from the gate, the photoelectric device functioning as a photodetector in various environments can have various applications. For example, in a low illuminance environment, the photodetector needs to achieve a high gain to improve the sensitivity. In a high illuminance environment, the photodetector can achieve a certain photodetection function even with a relatively low gain. Also, a high photosensitivity is required in some environments, and a relatively low photosensitivity is required in other environments.

Therefore, what is required is a photodetector capable of adjusting the photosensitivity by controlling the gain appropriately according to various use environments.

### SUMMARY

It is an object of the present disclosure to provide a photodetector capable of adjusting the gain according to a gate voltage applied and having a high sensitivity.

In accordance with one aspect of the present disclosure, a graphene photodetector includes: a semiconductor substrate doped with n-type impurity; a source insulation layer thrilled on the semiconductor substrate; a source electrode formed on the source insulation layer; a drain electrode formed on the semiconductor substrate opposed to the source insulation layer or the source electrode; a graphene channel formed on the semiconductor substrate and interposed between the source insulation layer and the source electrode; a gate insulation layer formed on the graphene channel and having light transmittance; and a gate electrode formed on the gate insulation layer and having light transmittance.

In accordance with another aspect of the present disclosure, a graphene photodetector includes: a semiconductor substrate doped with n-type impurity; a graphene channel forming a Schottky junction with the semiconductor substrate; a gate insulation layer formed on the graphene channel and having light transmittance; and a gate electrode formed on the gate insulation layer and configured to control a photocurrent according to an applied voltage.

According to the exemplary embodiment of the present disclosure described above, the photocurrent is generated by the electric field formed at the Schottky barrier even when no gate voltage is applied. Accordingly, this allows for a low-power photodetector. In addition, electron-hole pairs are formed in the semiconductors as well as the graphene, so that the photoabsorption rate and photoreactivity of the photodetector are increased, and the photoelectric conversion gain is increased or decreased in response to the gate voltage. By utilizing such gain, there is an advantage that the photoreactivity can be improved or the photoreactivity can be controlled according to the application example.

Further, the semiconductor substrate may be variously selected. That is, when a semiconductor substrate having a different Fermi level is selected or a semiconductor material having a different band gap is selected as a substrate, the photocurrent may be formed in different wavelength regions and the responsivity can be controlled.

### BRIEF DESCRIPTION OF DRAWINGS

FIG. 1 is a cross-sectional view showing a photoelectric device according to the prior art;

FIG. 2 is a cross-sectional view of a graphene photodetector according to an exemplary embodiment of the present disclosure;

FIGS. 3 to 5 are band diagrams for illustrating the operation of the graphene photodetector shown in FIG. 1 according to this exemplary embodiment of the present disclosure;

FIG. 6 is a graph showing the photoresponsivity of a graphene photodetector manufactured according to an exemplary embodiment of the present disclosure; and

FIG. 7 is a graph showing results of comparison between the photoresponsivity of the graphene photodetector according to an exemplary embodiment of the present disclosure and the photoresponsivities of competitive products.

### DETAILED DESCRIPTION

While the exemplary embodiments of the present disclosure are susceptible to various modifications and alternative forms, specific embodiments thereof are shown by way of example in the drawings and will herein be described in detail. It should be understood, however, that the drawings and detailed description thereto are not intended to limit the present disclosure to the particular form disclosed, but on the contrary, the intention is to cover all modifications, equivalents, and alternatives falling within the spirit and scope of the present disclosure as defined by the appended claims. In the drawings, like numerals refer to the same or similar elements or functionality throughout the several views.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Hereinafter, exemplary embodiments of the present disclosure will be described in more detail with reference to the accompanying drawings.

### Exemplary Embodiment

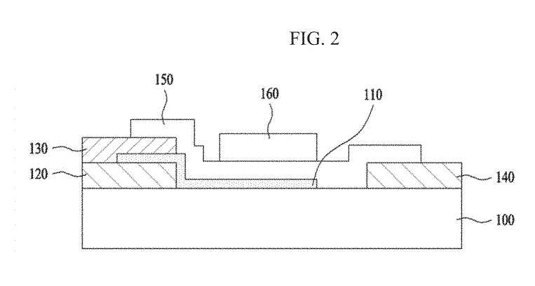

FIG. 2 is a cross-sectional view of a graphene photodetector according to an exemplary embodiment of the present disclosure.

Referring to FIG. 2, the graphene photodetector according to the exemplary embodiment of the present disclosure includes a semiconductor substrate 100, a graphene channel 110, a source insulation layer 120, a source electrode 130, a drain electrode 140, a gate insulation layer 150 and a gate electrode 160.

The semiconductor substrate 100 is preferably doped with n-type impurity. For example, the semiconductor substrate 100 may comprise one of silicon, MoS₂, germanium and TMDC (transition metal dichalcogenide) materials. It is to be understood that the semiconductor substrate 100 is not limited thereto and may have other semiconductor materials.

The graphene channel 110 is formed on the semiconductor substrate 100. The graphene channel 110 may be a single-layer graphene, which may be formed by patterning a graphene layer by a typical vapor deposition method on a catalytic metal substrate, and transferring it to the semiconductor substrate 100.

In addition, the source insulation layer 120 is formed on the semiconductor substrate 100, which is preferably made of silicon nitride, silicon oxide, or the like. The source insulation layer may be made of any material as long as it can achieve insulation between the source electrode 130 thereon and the semiconductor substrate 100.

The source electrode 130 is firmed on the source insulation layer 120. The source electrode 130 may be made of a variety of metal materials or polycrystalline silicon heavily doped. Particularly, a portion of the graphene channel 110 is interposed between the source electrode 130 and the source insulation layer 120, such that the graphene channel 110 is electrically connected to the source electrode 130. Accordingly, the source electrode 130 and the graphene channel 110 may be equipotential. The graphene channel 110 may be formed over the entire upper surface or a portion of the upper surface of the source insulation layer 120. It is to be noted that the graphene channel 110 on the source insulation layer 120 is extended to the exposed surface of the semiconductor substrate 100.

The drain electrode 140 is formed as opposed to the source electrode 130 with respect to the graphene channel 110. The drain electrode 140 is preferably made of a metal material or a polycrystalline silicon material heavily doped. Particularly, the drain electrode 140 is physically separated from the graphene channel 110. Accordingly, it is possible to implement a structure that the current generated in the graphene channel 110 does not directly flow to the drain electrode 140.

The gate insulation layer 150 is formed on the graphene channel 110. The gate insulation layer 150 may also work as a passivation layer for protecting the graphene channel 110 from the external environment. In addition, the gate insulation layer 150 is preferably made of Al₂O₃ which is a transparent material as it has to transmit incident light. The gate insulation layer 150 is preferably formed on a portion of each of the source electrode 130 and the drain electrode 140. Accordingly, a part of the upper surface of each of the source electrode 130 and the drain electrode 140 may be exposed. Additional wiring may be formed in the exposed portions. In addition, the gate insulation layer 150 shields the semiconductor substrate 100 and the graphene channel 110. Accordingly, the gate insulation layer 150 is interposed between the graphene channel 110 and the drain electrode 140 to provide insulation between the graphene channel 110 and the drain electrode 140.

The gate electrode 160 is formed on the gate insulation layer 150. The gate electrode 160 has to be made of a material having transparent property and conductivity. Therefore, the gate electrode 160 is preferably made of a ZnO material.

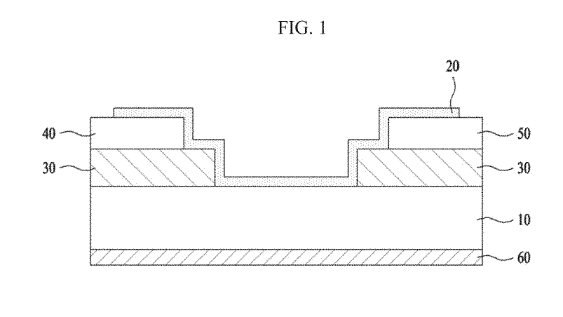

In the structure shown in FIG. 1, the graphene channel 110 has a single layer structure, and accordingly the band diagram has the shape of a Dirac cone. Further, a Schottky junction is formed between the graphene channel 110 and the semiconductor substrate 100. In particular, since the semiconductor substrate 100 is doped with n-type impurity, electrons are majority carriers in the semiconductor substrate 100.

If the voltage applied via the gate electrode 160 has a negative value, the Dirac point of the graphene channel 110 falls below the Fermi level of the gate electrode, and the Fermi level of the semiconductor substrate 100 falls below the Dirac point. Accordingly, holes are majority carriers in the graphene channel 110, and electrons are major carriers in the semiconductor substrate 100, and thus electrons in the conduction band induced in the graphene channel 110 or the semiconductor substrate 100 may move to the drain electrode 140 quickly to form photocurrent. The photocurrent is based on the assumption that light illuminated from the outside passes through the gate electrode 160, the gate insulation layer 150 and the graphene channel 110 to be incident on the semiconductor substrate 100. That is, in the electron-hole pairs generated by the light incident on the semiconductor substrate 100 and the graphene channel 110, the electrons move to the drain electrode 140 via the semiconductor substrate 100 while the holes move to the graphene channel 110.

If the voltage applied via the gate electrode 160 has a positive value, the Dirac point of the graphene channel 110 is set to be equal to or higher than the Fermi level of the gate electrode 160. In addition, the Fermi level of the semiconductor substrate 100 rises relative to the Dirac point of the graphene channel 110. As the Fermi level rises, the probability that the holes generated in the semiconductor substrate 100 move to the graphene channel 110 is reduced. Complementary with this, the probability that electrons generated in the graphene channel 110 or the semiconductor substrate 100 move to the drain electrode 140 is also reduced. As a result, the photocurrent generated by the incidence of light is also reduced.

In this embodiment, the Dirac point corresponds to the Fermi level of the graphene channel 110 and the semiconductor substrate 100 when no bias is applied to the gate electrode 160, which is equal to the Fermi level of the gate electrode 160.

In FIG. 2, it is desirable that the graphene channel 110 is physically separated from the drain electrode 140. If the graphene channel 110 and the drain electrode 140 are in physical contact with each other on the semiconductor substrate 100, the Schottky barrier between the graphene channel 110 and the semiconductor substrate 100 may lose the current control function. As a result, there may be a problem that the carriers generated on the semiconductor substrate 100 directly move to the drain electrode 140. In addition, as the probability that the holes in the graphene channel 110 move to the drain electrode 140 and recombine with electrons is increased, there arises a problem that the photocurrent substantially cannot be formed.

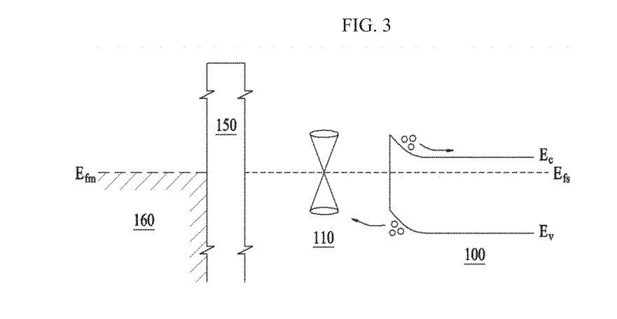

FIGS. 3 to 5 are band diagrams for illustrating the operation of the graphene photodetector shown in FIG. 1 according to this exemplary embodiment of the present disclosure.

Referring to FIG. 3, a band diagram is shown when no bias is applied to the gate electrode 160 or when the voltage difference between the gate electrode 160 and the source electrode 130 is 0 V. Further, in this embodiment, the gate voltage represents the voltage difference between the gate electrode 160 and the source electrode 130.

The Fermi level E_{fm}, of the gate electrode 160 and the Dirac point of the graphene channel 110 have the same value, which is shown as the same Fermi level. Further, the graphene channel 110 is configured as a single-layer graphene, which forms a junction with the semiconductor substrate 100 doped with n-type impurity. Therefore, the Fermi level E_{fm} of the gate electrode 160 having metallic properties and the Fermi level E_{fs} of the semiconductor substrate 100 have the same value. Further, a Schottky junction is formed between the graphene channel 110 and the semiconductor substrate 100, thereby forming a Schottky barrier. As the semiconductor substrate 100 is doped with n-type impurity, the Fermi level E_{fs} of the semiconductor substrate 100 is increased as compared with an intrinsic semiconductor, and the energy barrier is formed at the interface of the junction with the graphene channel 110.

When light is incident from the outside, electron-hole pairs are generated in the graphene channel 110 or in a portion of the semiconductor substrate 100 around the interface with the graphene channel 110. Electrons in the conduction band generated at the interface between the semiconductor substrate 100 and the graphene channel 110 move to the bulk region of the semiconductor substrate 100 along the energy slope and are supplied to the drain electrode. Further, the holes of the valence band go over the energy barrier and move to the graphene channel 110. This forms the photocurrent.

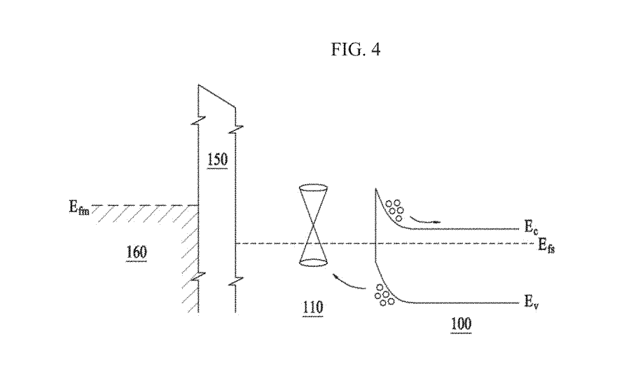

Referring to FIG. 4, a negative voltage is applied via the gate electrode 160. That is, the voltage difference between the gate electrode and the source electrode has a negative value. The Dirac point of the graphene channel 110 in response to the bias of the gate electrode 160 having a negative value is set to be equal to or less than the Fermi level E_{fm} of the gate electrode 160. In addition, the Fermi level E_{fs} of the semiconductor substrate decreases below the Dirac point of the graphene channel 110. Accordingly, a high Schottky barrier is formed at the interface between the graphene channel 110 and the semiconductor substrate 100.

Further, when light is incident, electron-hole pairs are generated in the interface between the semiconductor substrate 100 and the graphene channel 110. A majority of the electrons in the conduction band may move to the drain electrode through the bulk region of the semiconductor substrate 100 over the steep energy slope of the conduction band. Complementary with this, the holes in the valence band may move to the graphene channel 110 over the steep energy slope of the valence band. Therefore, a higher photocurrent can be obtained as compared with FIG. 3.

That is, the photocurrent increases as the gate voltage has a more negative value for a given amount of light.

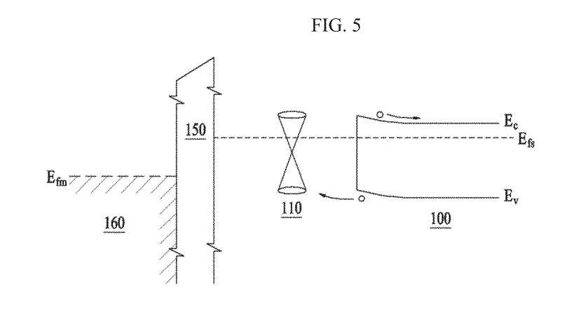

Referring to FIG. 5, a positive voltage is applied via the gate electrode 160. Therefore, the Dirac point of the graphene channel has a higher value than the Fermi level E_{fm} of the gate electrode 160, and the Fermi level E_{fs} of the semiconductor substrate 100 has a value higher than the Dirac point of the graphene channel 110. This means that the energy barrier at the interface between the semiconductor substrate 100 and the graphene channel 110 is reduced. That is, the energy barrier is reduced at the interface of the graphene channel 110 and the bulk region of the semiconductor substrate 100.

When light is incident, electron-hole pairs are generated in the semiconductor substrate 100. The electrons in the conduction band formed by the electron-hole pairs move along the slope of the conduction band at the junction interface between the semiconductor substrate 100 and the graphene channel 110. However, since the conduction band has a low slope, the probability that electrons in the conduction band move to the drain electrode is reduced. This may be equally applied to the holes in the valence band of the semiconductor substrate 100. That is, the probability that the generated holes in the valence band move to the graphene channel 110 is reduced. This reduces the photocurrent.

That is, as shown in FIGS. 3 to 5, the Fermi level E_{fs} of the semiconductor substrate 100 is changed according to the application of the gate voltage, and the Schottky barrier at the interface between the graphene channel 110 and the semiconductor substrate 100 is changed. Particularly, as the light is incident, the electron-hole pairs move to the graphene channel 110 or the semiconductor substrate 100 along The slope of the energy band. That is, the electrons in the conduction band of the semiconductor substrate 100 generated at the interface with the graphene channel 110 move to the drain electrode along the slope of the energy band, while the holes in the valence band of the semiconductor substrate 100 move to the graphene channel 110 along the slope of the energy band. This forms a potential between the source electrode and the drain electrode and forms a photocurrent.

Accordingly, depending on the pattern of the applied gate voltage, the generated photocurrent may be distributed in various ways for the same amount of incident light.

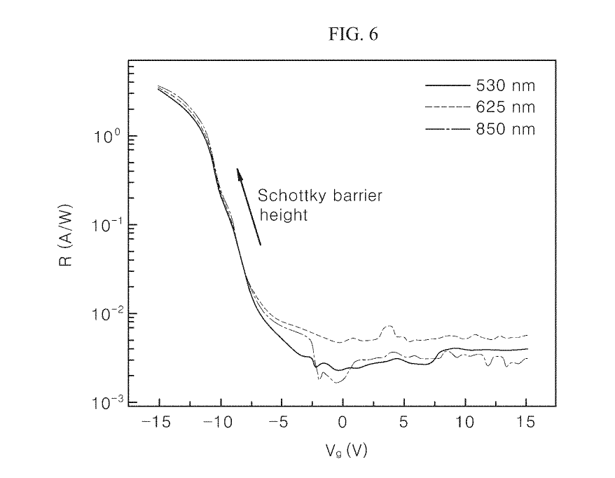

FIG. 6 is a graph showing the photoresponsivity of a graphene photodetector manufactured according to an exemplary embodiment of the present disclosure.

Referring to FIG. 6, the semiconductor substrate is made of silicon and is doped with n-type impurity. P-dopant is used, the doping concentration is ˜10¹⁵ cm⁻³, and the thickness of the silicon substrate is about 500 μm. The source insulation layer is made of SiO₂ and has a thickness of 90 mm. The source electrode and the drain electrode are made of Au, and have thicknesses of 50 μm. The gate insulation layer is made of Al₂O₃ and has the thickness of 30 nm. The gate electrode includes ZnO and has the thickness of 30 nm. A graphene channel made of a single graphene layer is formed on the semiconductor substrate and the source insulation layer. In particular, as shown in FIG. 2, the length of the graphene channel extending from the end of the source insulation layer to the drain electrode is 3 μm to 5 μm. The width of the graphene channel formed in the direction perpendicular to FIG. 1 is approximately 16 μm.

In FIG. 6, the graphene photodetector is irradiated with light having wavelengths of 530 nm, 625 nm, and 850 nm, respectively. Responsivity is measured when the gate voltage Vg defined as the voltage difference between the gate electrode and the source electrode is set to −15V to 15V. The responsivity is expressed in Ampere/Watt (A/W) as a ratio of the output current to the power of a specific wavelength of incident light. Further, it is known that the sensitivity of the photodetector is higher as the responsivity R is higher.

When the gate voltage Vg is in the range of 0 V to 15 V, the responsivity has a very low value of 10⁻² or less. This is because the Schottky barrier between the graphene channel and the semiconductor substrate decreases or there is no change.

It can also be seen that the responsivity exponentially increases in the region where the gate voltage Vg is set to −5 V to −15 V This phenomenon is explained by the increase of the Schottky barrier. In particular, the responsivity R increases to about 80 A/W as the gate voltage Vg approaches −15 V, regardless of the wavelength of the light Therefore, it is possible to change the responsivity R by adjusting the level of the gate voltage Vg, and a high responsivity can be ensured.

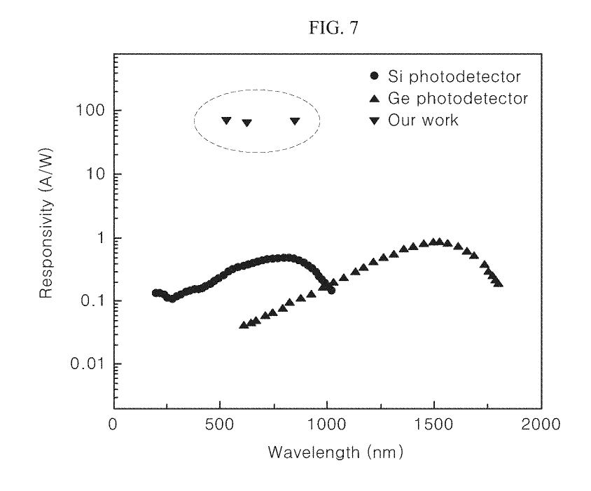

FIG. 7 is a graph showing results of comparison between the photoresponsivity of the graphene photodetector according to an exemplary embodiment of the present disclosure and the photoresponsivities of competitive products.

In the graph shown in FIG. 7, the symbols ▾ indicate the responsivity of the graphene photodetector of FIG. 6. In addition, the symbols indicate the responsivity of a Si-based photodetector (model No. S1337-BQ from HAMAMATSU). The symbols ▴ indicate the responsivity of a Ge-based photodetector (model No. J16 SERIES from TELEDYNE JUDSON TECHNOLOGIES).

As shown in FIG. 7, it can be seen that the responsivity of the graphene photodetector according to the exemplary embodiment of the present disclosure is much higher than the responsivities of the existing competitive products.

According to the exemplary embodiment of the present disclosure described above, the photocurrent is generated by the electric field formed at the Schottky barrier even when no gate voltage is applied. Accordingly, this allows for a low-power photodetector. In addition, electron-hole pairs are formed in the semiconductors as well as the graphene, so that the photoabsorption rate and photoreactivity of the photodetector are increased, and the photoelectric conversion gain is increased or decreased in response to the gate voltage. By utilizing such gain, there is an advantage that the photoreactivity can be improved or the photoreactivity can be controlled according to the application example.

Further, the semiconductor substrate may be variously selected. That is, when a semiconductor substrate having a different Fermi level is selected or a semiconductor material having a different band gap is selected as a substrate, the photocurrent may be formed in different wavelength regions and the responsivity can be controlled.

What is claimed is:

1. A graphene photodetector comprising:
a semiconductor substrate doped with n-type impurity;
a source insulation layer formed on the semiconductor substrate;
a source electrode formed on the source insulation layer;
a drain electrode formed on the semiconductor substrate opposed to the source insulation layer or the source electrode;
a graphene channel formed on the semiconductor substrate and interposed between the source insulation layer and the source electrode;
a gate insulation layer formed on the graphene channel and having light transmittance; and
a gate electrode formed on the gate insulation layer and having light transmittance.

2. The graphene photodetector according to claim 1, wherein the graphene channel is formed on the semiconductor substrate between the source insulation layer and the drain electrode, and is physically separated from the drain electrode.

3. The graphene photodetector according to claim 2, wherein the gate insulation layer shields a portion of a surface of the semiconductor substrate exposed between the graphene channel and the drain electrode.

4. The graphene photodetector according to claim 1, wherein the semiconductor substrate comprises silicon or MoS₂.

5. The graphene photodetector according to claim 1, wherein, if light having passed through the gate electrode and the gate insulation layer is incident on an interface between the graphene channel and the semiconductor substrate, a Schottky barrier thrilled by a junction of the graphene channel and the semiconductor substrate generates a photocurrent.

6. The graphene photodetector according to claim 5, wherein, upon the light being incident, electrons in a conduction band around the junction between the semiconductor substrate and the graphene channel are moved to a bulk region of the semiconductor substrate, while holes in a valence band around the junction between the semiconductor substrate and the graphene channel are moved to the graphene channel.

7. The graphene photodetector according to claim 6, wherein the electrons having moved to the bulk region of the semiconductor substrate move to the drain electrode to form the photocurrent.

8. The graphene photodetector according to claim 5, wherein the Schottky barrier is changed by a gate voltage, wherein the gate voltage is equal to a voltage difference between the gate electrode and the source electrode.

9. The graphene photodetector according to claim 8, wherein the Schottky barrier increases and the photocurrent increases as the gate voltage has a more negative value.

10. The graphene photodetector according to claim 8, wherein the Schottky barrier decreases and the photocurrent decreases as the gate voltage has a more positive value.

11. A graphene photodetector comprising:
a semiconductor substrate doped with n-type impurity;
a graphene channel forming a Schottky junction with the semiconductor substrate;
a gate insulation layer formed on the graphene channel and having light transmittance; and
a gate electrode formed on the gate insulation layer and configured to control a photocurrent according to an applied voltage.

12. The graphene photodetector according to claim 11, wherein the graphene channel is connected between a source insulation layer formed on the semiconductor substrate and a source electrode, and is physically separated from the drain electrode.

13. The graphene photodetector according to claim 12, wherein electrons forming the photocurrent flow to the semiconductor substrate and the drain electrode by the Schottky junction.
